(19) United States
(12) Patent Application Publication
(10) Pub. No.: US 2023/0220962 A1
(43) Pub. Date: Jul. 13, 2023

(54) Luminaire Design Retrofitting Method and Computer-Controlled Method Thereof

(71) Applicant: Schreder S.A., Bruxelles (BE)

(72) Inventor: Philippe Frankinet, Horion-Hozémont (BE)

(21) Appl. No.: 18/000,452

(22) PCT Filed: Jun. 2, 2021
(86) PCT No.: PCT/EP2021/064865

§ 371 Date: Dec. 1, 2022

(30) Foreign Application Priority Data
Jun. 2, 2020 (NL) 2025720

(51) Int. Cl. F21S 8/08; G06F 30/20

(52) U.S. Cl. CPC F21S 8/086; G06F 30/20; F21W 2131/103

(57) ABSTRACT

A method for retrofitting a lighting site. The lighting site includes at least one pathway. The method comprises: obtaining at least one visual representation of the lighting site to be retrofitted, said lighting site corresponding to a location for installing at east one luminaire; extracting, from the at least one visual representation, at least one luminaire installation characteristic; obtaining, based on the at least one luminaire installation characteristic and a database with a plurality of luminaire designs, a list comprising at least one luminaire design of said plurality of luminaire designs, said at least one luminaire design being suitable for being installed at the lighting site.

### FIELD OF INVENTION

The field of the invention relates to luminaire design retrofitting methods. Particular embodiments relate to a luminaire design retrofitting method, and a computer-controlled method, in order to retrofit with a suitable luminaire design a lighting site.

### BACKGROUND

Methods to compose luminaire designs are readily available and typically comprise the filling out of an extensive list of parameters, optical and geometrical parameters for example, in order to determine the best suited theoretical luminaire design for a given lighting site. The list of parameters is usually provided manually by a user of a computer-implemented method. These parameters reflect the optical considerations and the installation possibilities of the lighting site. The user can then tinker with some parameters to obtain a luminaire design actually corresponding to an existing product. Other parameters can be considered to account for constraints from different origins: optimization, regulation, monetary, product availability, etc. Obtaining such luminaire design is a time consuming operation and the computer-implemented method is typically not user-friendly for the non-initiated user. Also, depending on the user, some information relevant for the luminaire design and/or the lighting site may be easily overlooked.

### SUMMARY

The object of embodiments of the invention is to provide a luminaire design retrofitting method and a computer-controlled method thereof, allowing for a user-friendly and modulable obtention of a luminaire design.

According to an aspect of the invention, there is provided a method for retrofitting a lighting site. The lighting site includes at least one pathway. The method comprises:
obtaining at least one visual representation of a lighting site to be retrofitted, said lighting site corresponding to a location for installing at least one luminaire;
extracting, from the at least one visual representation, at least one luminaire installation characteristic;
obtaining, based on the at least one luminaire installation characteristic and a database with a plurality of luminaire designs, a list comprising at least one luminaire design of said plurality of luminaire designs, said at least one luminaire design being suitable for being installed at the lighting site.
   By using as a base for extraction at least one visual representation of a lighting site, the filling out of luminaire installation characteristics to obtain at least one luminaire design is greatly simplified, which improves the overall user-friendliness of the method. The lighting site is a site to be retrofitted. In other words, a location of at least one base support to support at least one luminaire of the lighting site is visible in the at least one visual representation of the lighting site. By visible, it is meant that the location may be marked visually on site, or artificially a posteriori after an initial visual representation, for example a photo, of the lighting site has been obtained. The base support may correspond to a pole or a surface onto which a luminaire head may be provided, optionally with a luminaire head bracket. The base support need not be physically present on the lighting site in order for its location or the location of the luminaire to be visible on the lighting site.

Extraction methods based on the processing of the at least one visual representation are not described here but are known to the skilled person. The at least one luminaire installation characteristic may correspond to optical characteristics of the environment of the lighting site to be illuminated, and/or to dimensions relevant for the installation of a luminaire. In an embodiment, the extraction of the at least one installation characteristic may be followed by a manual correction or confirmation of the at least one installation characteristic extracted.

The plurality of luminaire designs in the database comprising the plurality of luminaire designs may each be associated to parameters and a light distribution from which the suitability to the extracted optical characteristics of the environment of the lighting site to be illuminated and/or to extracted dimensions relevant for the installation of a luminaire may be deducted. By an elimination process, a list of at least one suitable luminaire design can be obtained. By suitability, it is meant the ability for the luminaire design to satisfy some lighting standards, e.g. a public road lighting standard or recommendations such as EN 13201, IES RP-8, CIE 115, respective to the environment of the lighting site, thereby allowing for an illumination giving a visibility above a predetermined level for users of the lighting site, as well as giving a predetermined illumination safety, e.g. illumination intensity below a blinding intensity, light emitted within a certain arc to avoid glaring angles.

More than one visual representation of the lighting site may be obtained and used for completeness. Since the filling out of the at least one luminaire installation characteristic is processed from the at least one visual representation, instead of manually as usually done in the prior art, the method is more user-friendly.

According to a preferred embodiment, the at least one luminaire installation characteristic is at least one of: a pathway width, an interval distance between two neighboring luminaire base supports, a pathway surface material, a pathway surface optical properties, a height of a luminaire head of the at least one luminaire, a number of lanes of the pathway, one or more circulation directions of the pathway, a lateral distance between the pathway and the at least one luminaire base support, a lateral dimension of a hard shoulder of the pathway, an arrangement pattern of a group of luminaires including the at least one luminaire, a bracket length of the luminaire head of the at least one luminaire, an inclination of the luminaire head of the at least one luminaire, a location of the at least one luminaire base support respective to the one or more circulation directions, a proximity with a neighboring building, characteristics of the neighboring building, a number of luminaire heads per base support, a presence of a conflict area in the lighting site, a type of the pathway. Preferably, a plurality of installation characteristics are extracted and the at least one installation characteristic is at least two of the above, more preferably at least three of the above.

The conflict area may be defined (see also the CIE 115-2010 standard) as an area where there is an increased potential for collision between road users, e.g. entry or exit lanes to the highway, crossroads, roundabouts, pedestrian crossings, etc.

The pathway may be a pathway of a lighting site suitable for outdoor luminaires which is used as a path for vehicles and/or pedestrians. By lighting site for outdoor luminaires, it is meant roads, tunnels, industrial plants, stadiums, airports, harbors, rail stations, campuses, parks, cycle paths, pedestrian paths, or pedestrian zones for example, and outdoor luminaires can be used notably for the lighting of an outdoor area, such as roads and residential areas in the public domain, private parking areas and access roads to private building infrastructures, etc. In other embodiments according to the invention, the pathway may be located indoors, such as in a warehouse or an industry hall.

According to an exemplary embodiment, the method further comprises providing an input corresponding to another luminaire installation characteristic; and the obtaining of the list of the at least one luminaire design is further based on the another luminaire installation characteristic.
In this way, additional luminaire installation characteristics may be inputted to complete the at least one luminaire installation characteristic extracted from the at least one visual representation. Luminaire installation characteristics may thus be conveniently inputted from various sources. For example the input provided may be a manual input by a user using an inputting means, e.g. a keyboard. The another luminaire installation characteristic may originate from a database of known luminaire installation characteristics and/or based from on-site measured data.
According to a typical embodiment, the method further comprises providing an input corresponding to a preferential parameter relative to the plurality of luminaire designs; and sorting the list of the at least one luminaire design based on the preferential parameter.
By this approach, one can obtain a more comprehensive view of the list according to one's interests. The preferential parameter may be a cost, a technical option, a management option, an aesthetical consideration, maintenance factors, a brand of a luminaire part of the at least one luminaire design, a protocol such as communication protocol, a number of luminaire parts included in the at least one luminaire design, protectors type (e.g. glass), a certification, a lighting light distribution, a luminaire working temperature, a lighting life time, a luminaire class, a luminaire total cost of ownership, a luminaire installation method, a control system of the luminaire, a maximum number of mounting tools to use, etc. For example, the certification may be related to an ecological label of a manufacturing company and/or of luminaire parts of the luminaire design, an IP-rating of the luminaire design, a resistance rating to shocks and/or vibrations, etc.
According to a preferred embodiment, the method further comprises obtaining, from a regulation database, a lighting regulation associated to the lighting site; and the obtaining of the list of the at least one luminaire design is further based on the obtained lighting regulation.
In this manner, the list may be funneled further to be better suited to the location of the lighting site by taking into account another kind of parameter. This improves the modularity of the method in obtaining suitable luminaire designs for the lighting site. The lighting regulation may correspond to a legal obligation or recommendation based on the class of the identified pathway, the amount of traffic, the type of users of the pathway, etc. The regulation database may be a nation-wide database, a region-wide database, a city-wide database, or a local-wide database. In an embodiment, the obtaining of the lighting regulation may be based on the geo-coordinates of the lighting site. Additionally or alternatively, the obtaining of the lighting regulation may be at least partially based on the extracted installation characteristic, e.g. the number of lanes of the pathway. In an embodiment, the obtaining of the lighting regulation may be followed by a manual correction or confirmation of the lighting regulation associated to the lighting site.
Also, the obtaining of the lighting regulation may be achieved by a manual entry.
Also, the at least one luminaire design may comprise an optical assembly configured for shaping the light distribution from the at least one luminaire design. The optical assembly may comprise: a frame with at least one opening; a plurality of optical modules; a support means; and an assembling means for assembling the plurality of optical modules to the frame, e.g. by ultrasonic welding, heat staking, plastic deformation. At least one optical module of the plurality of optical modules is provided per opening of the at least one opening. The support means is provided to each of the plurality of optical modules and/or to each of the at least one opening, said support means being configured for supporting the optical module at least partially within the opening of the frame. The assembling means may comprise a plurality of portions configured to assemble the plurality of optical modules to the frame preferably such that the plurality of optical modules is locked to the support means. According to an exemplary embodiment the optical assembly is an optical assembly as disclosed in NL 2026155 which is included herein by reference.

There may be one or more optical modules per opening of the frame. For example, an opening may be dimensioned to receive two optical modules, one next to the other. Optionally, at least two optical modules may be assembled together using e.g. interlocking mechanical means, glue, and/or by magnetic force. Also, there may be a plurality of openings in the frame. So, the optical modules may be picked individually to custom design the optical properties of the optical assembly. Therefore, a high flexibility of the optical assembly may be reached in terms of light patterning.

The plurality of optical modules may be the same or different. The plurality of optical modules may be picked from a storage comprising many different optical modules, and this picking may be based on the desired light distribution of the luminaire design in which the resulting optical assembly is to be included. Thus, a highly modular luminaire design is obtained.

According to an exemplary embodiment, the method further comprises obtaining, from a stock database, a list of available luminaire parts; and the obtaining of the list of the at least one luminaire design is further based on the obtained list of available luminaire parts.
In this way, the obtained list of the at least one luminaire design reflects an actual product availability. Indeed the luminaire design may comprise a certain number of parts to be gathered with various parts being essential or interchangeable. The availability of parts may change the overall characteristics of a luminaire design. The stock database may be luminaire parts available in a stock of a local provider, in a stock of a luminaire producer, in a catalogue of products, or in a personal stock. The availability may be further distinguished between available in stocks, discontinued, in production, and/or with a time indication of the availability on the lighting site for installation. The list of available luminaire parts may also comprise a quantity of available luminaire parts, an end-of-life date of available luminaire parts, a manufacturing country of the luminaire parts, an ecological label of the luminaire parts. Such way of refining the list of the at least one luminaire design provides for a more informed choice of a luminaire design based on a reality of the readily available items. In an embodiment, the obtaining of the list of the at least one luminaire design may be based on luminaire designs favoring available luminaire parts whose quantity in stocks is high, which are subject to a special price offer, and/or which are close to the end-of-life date.

Also, in an embodiment, the obtaining of the list may be followed by the provision of a purchase selection interface. The purchase selection interface may allow the user, after selection of the at least one desired luminaire design from the list of the at least one luminaire design, to conclude by ordering the at least one desired luminaire design for retrofitting the lighting site.

According to a preferred embodiment, the method further comprises outputting an altered visual representation of the lighting site with at least one installed luminaire, based on the list of the at least one luminaire design and on the at least one visual representation of the lighting site.
In this manner, one can better visualize the aesthetics of the lighting site with an installed luminaire from the list of the at least one luminaire design. In one embodiment, when presented with the list, a user may pick a luminaire design from the list using a selection interface. Based on the at least one visual representation of the lighting site, a composite altered visual representation of the lighting site may be processed to integrate the picked luminaire design as an installed luminaire on the lighting site. Preferably, the outputted altered visual representation is outputted via an AR (altered reality) device. Such a visualization improves the user-friendliness of the method by allowing another parameter, aesthetics, to be evaluated.
According to an exemplary embodiment, the at least one visual representation is any one, or a combination, of: a photograph of the lighting site, a video of the lighting site, a map of the lighting site, a three-dimensional view of the lighting site, a street-level visualization of the lighting site.

The map of the lighting site may be a technical map of the lighting site, an architectural blueprint of the lighting site, a cadastral map, a topographic map, or an architectural project view of the lighting site.

According to a preferred embodiment, the at least one visual representation comprises a first and a second visual representation of the lighting site, said first visual representation being different from said second visual representation; and the extracting of the at least one luminaire installation characteristic is based on the first and the second visual representations of the lighting site.
In this way, multiple sources may be used in order to improve the precision of the extracted at least one luminaire installation characteristic. In another embodiment, the plurality of visual representations may provide complementary information which, when processed, allows the extraction of the at least one luminaire installation characteristic. Different or similar extraction methods may be used on the first and second visual representations of the lighting site to extract information, and optionally may be further processed. By combining different visual information, one may obtain luminaire installations characteristics not otherwise extractable.
In an exemplary embodiment one or more first visual representations of the lighting site may be used to extract a first luminaire installation characteristic, and one or more second visual representations of the lighting site may be used to extract a second luminaire installation characteristic.
According to an exemplary embodiment, the obtaining of the list of the at least one luminaire design is further based on another at least one luminaire installation characteristic of another lighting site.
In this manner, a certain uniformity between lighting sites may be attained. The at least one luminaire installation characteristic and the another at least luminaire installation characteristic may be of similar or different kinds. In one embodiment, the another lighting site does not need to be retrofitted and the another at least one luminaire installation characteristic allows to improve the likeness in the list of the at least one luminaire design between the lighting site and the another lighting site. In another embodiment, the another lighting site is to be retrofitted and the obtaining of the list of the at least one luminaire design allows optimizing the suitability to multiple lighting sites. It is to be noted that the another at least one luminaire installation characteristic may be provided manually, and/or extracted from an obtained visual representation, and/or originate from a database.
According to a preferred embodiment, the at least one visual representation comprises an indication corresponding to a location of the at least one luminaire base support within the lighting site.
In this way, the extraction of the at least one luminaire installation characteristic may be more accurate due to the visually distinctly identified location of the at least one luminaire base support in its environment.
According to an exemplary embodiment, the lighting site corresponds to the location for installing, for the at least one luminaire, at least one luminaire head, optionally combined with an associated luminaire head bracket, to at least one existing base support of the lighting site, e.g. a luminaire pole.
In this manner, more information is available in the at least one visual representation for the extraction of the at least one luminaire installation characteristic since the at least one base support of the at least one luminaire is visible. The at least one luminaire design of the list may be obtained based on a more restricted framework since the at least one base support may impose constraints and since only a luminaire head, optionally combined with an associated luminaire head bracket, needs to be installed.
The skilled person will understand that the hereinabove described technical considerations and advantages for embodiments of a method for retrofitting a lighting site also apply to the below described corresponding computer program embodiments, mutatis mutandis.
According to a second aspect of the invention, there is provided a computer program. The computer program comprises instructions which, when the program is executed by a computer, cause the computer to carry out the method for retrofitting a lighting site as hereinabove described.
The skilled person will understand that the hereinabove described technical considerations and advantages for embodiments of a method for retrofitting a lighting site and for computer program embodiments also apply to the below described corresponding computer controlled system for retrofitting a lighting site embodiments, mutatis mutandis.
According to a third aspect of the invention, there is provided a computer controlled system for retrofitting a lighting site. The lighting site includes at least one pathway. The system includes:
a data entry means adapted to receive:
   at least one visual representation of the lighting site to be retrofitted, said lighting site corresponding to a location for installing at least one luminaire;
   a database comprising a plurality of luminaire designs;
a memory coupled to said data entry means for storing said at least one visual representation, and said database comprising the plurality of luminaire designs;
a processor coupled to said memory;
a display coupled to said processor;
wherein the processor is further configured for:
   obtaining, from the memory, the at least one visual representation of the lighting site;
   extracting from the at least one visual representation at least one luminaire installation characteristic;
   obtaining, based on the at least one luminaire installation characteristic, a list of at least one luminaire design of the plurality of luminaire designs, said at least one luminaire design being suitable for being installed at the luminaire site;
   outputting the list of the at least one luminaire design via the display.
      According to a preferred embodiment, the processor is further configured for:
providing an input interface for inputting another installation characteristic; and
obtaining the list of the at least one luminaire design further based on the another installation characteristic.
   According to an exemplary embodiment, the processor is further configured for:
providing an input interface for inputting a preferential parameter; and
sorting the list of the at least one luminaire design based on the preferential parameter.
   According to a preferred embodiment, the system further comprises a regulation database, and the processor is further configured for:
obtaining, from the regulation database, a lighting regulation associated to the lighting site; and
obtaining the list of the at least one luminaire design further based on the obtained lighting regulation.
   In an embodiment, the regulation database may be stored in the memory of the system and the obtaining of the lighting regulation may be achieved by reading the regulation database in the memory. In another embodiment, the system may further comprise a communication means configured for communication with the regulation database located remotely.
   According to an exemplary embodiment, the system further comprises a stock database, and the processor is further configured for:
obtaining, from a stock database, a list of available luminaire parts; and
obtaining the list of the at least one luminaire design further based on the obtained list of available luminaire parts.
   In an embodiment, the stock database may be stored in the memory of the system and the obtaining of the list of available luminaire parts may be achieved by reading the stock database in the memory. In another embodiment, the system may further comprise a communication means configured for communication with the stock database located remotely.
   According to a preferred embodiment, the system further comprises an inputting means configured for inputting, through the inputting means via a selection interface, a selected luminaire design from the list of the at least one luminaire design, and the processor is configured for:
altering the at least one visual representation of the lighting site with at least one installed luminaire, based on the list of the at least one luminaire design and on the at least one visual representation of the lighting site; and
outputting the at least one altered visual representation via the display, and/or outputting the at least one altered visual representation via another display included in the computer controlled system.
   According to an exemplary embodiment, the data entry means is further adapted to receive:
a second visual representation of the lighting site different from a first visual representation of the at least one visual representation; and

wherein the processor is further configured for:
extracting the at least one luminaire installation characteristic based on the first and on the second visual representations of the lighting site.
   In this way, multiple sources may be used in order to improve the precision of the extracted at least one luminaire installation characteristic. In another embodiment, the plurality of visual representations may provide complementary information which, when processed, allows the extraction of the at least one luminaire installation characteristic. Different or similar extraction methods may be used on the first and second visual representations of the lighting site to extract information, and optionally may be further processed. By combining different visual information, one may obtain luminaire installations characteristics not otherwise extractable.
   In an exemplary embodiment one or more first visual representations of the lighting site may be used to extract a first luminaire installation characteristic, and one or more second visual representations of the lighting site may be used to extract a second luminaire installation characteristic.
   According to a preferred embodiment, the processor is further configured for:
obtaining the list of the at least one luminaire design further based on another at least one luminaire installation characteristic of another lighting site.

### BRIEF DESCRIPTION OF THE FIGURES

This and other aspects of the present invention will now be described in more detail, with reference to the appended drawings showing a currently preferred embodiment. Like numbers refer to like features throughout the drawings.

FIG. 1 illustrates schematically an exemplary embodiment of a method for retrofitting a lighting site;

FIG. 2 depicts an outline of a lighting site according to an exemplary embodiment of the invention;

FIGS. 3A-3B depict two different views of a list of luminaire designs obtained according to exemplary embodiments of the invention;

FIGS. 4A-4C depict visual representations of a lighting site according to exemplary embodiments of the invention.

### DESCRIPTION OF EMBODIMENTS

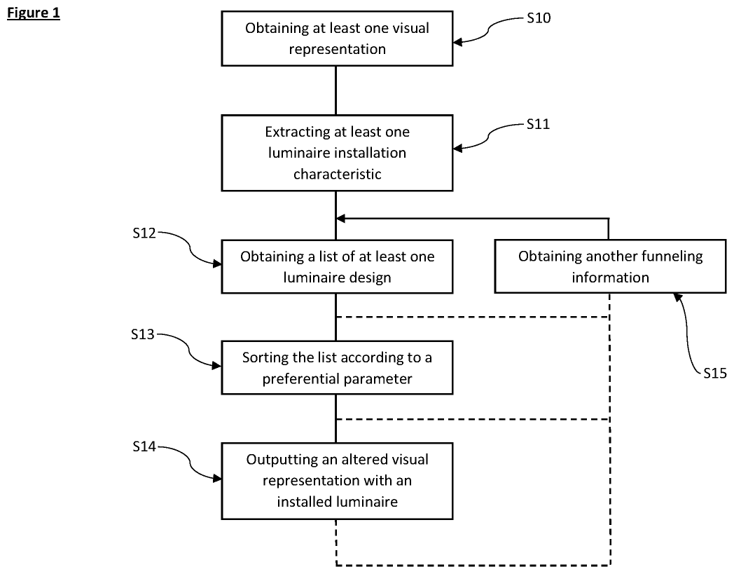

FIG. 1 illustrates schematically an exemplary embodiment of a method for retrofitting a lighting site according to the present invention.

The method of the present invention allows to retrofit a lighting site. The lighting site may correspond to any space to be illuminated with a location for installing at least one luminaire. The lighting site typically comprises a pathway that can be taken by vehicles and/or pedestrians. The pathway may be a pathway on a lighting site suitable for outdoor luminaires By lighting site for outdoor luminaires, it is meant roads, tunnels, industrial plants, stadiums, airports, harbors, rail stations, campuses, parks, cycle paths, pedestrian paths, or pedestrian zones for example, and outdoor luminaires can be used notably for the lighting of an outdoor area, such as roads and residential areas in the public domain, private parking areas and access roads to private building infrastructures, etc. In other embodiments according to the invention, the pathway may be located indoors, such as in a warehouse or an industry hall.

Since the method is for retrofitting, it is presupposed that the location of the at least one luminaire to be installed can be identified on the lighting site. In other words, a complete luminaire may already be installed on the lighting site and there is an interest in replacing it or at least replacing part of it, or only part of the luminaire is present on the lighting site, e.g. the base support of the luminaire is already mounted or the location where the base support will be is identifiable.

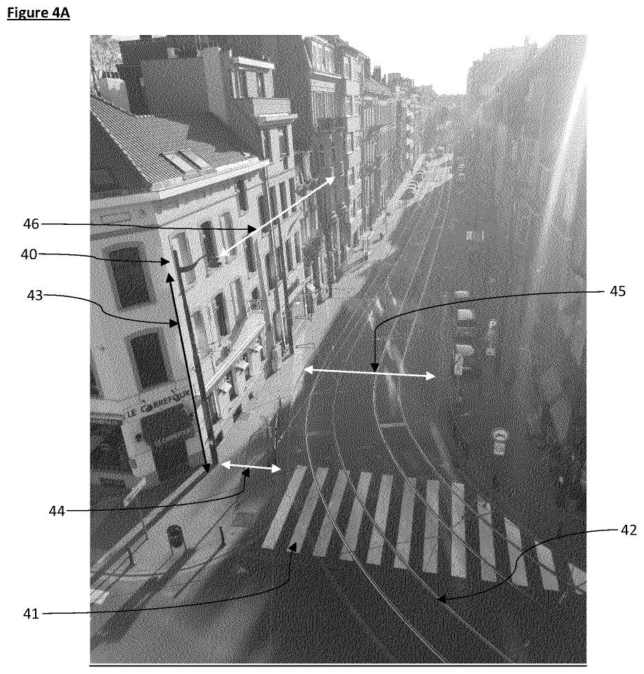

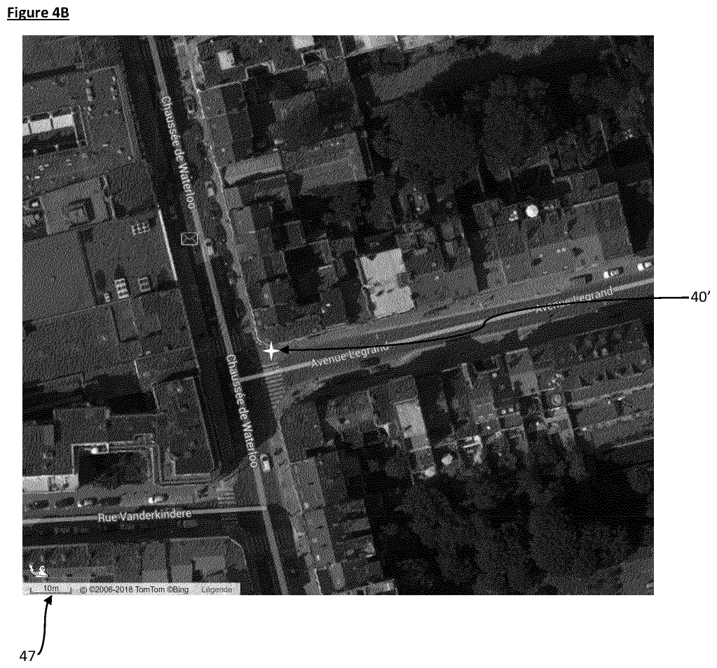

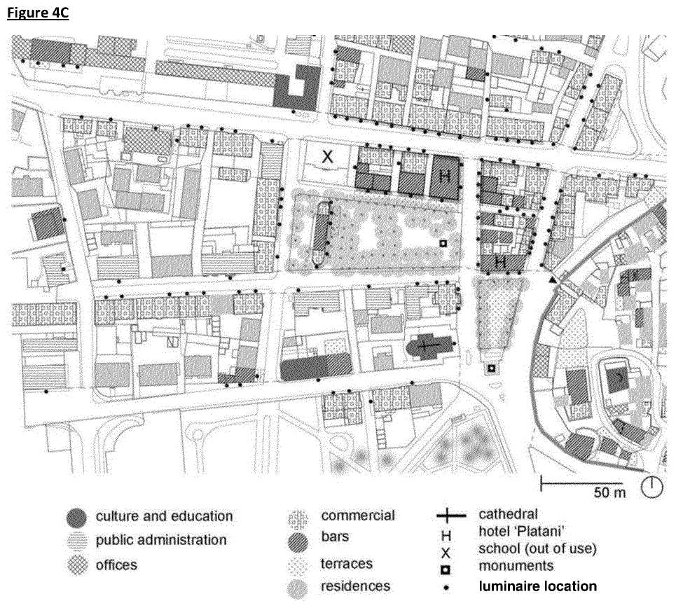

As can be seen in the embodiment of FIG. 1, the method comprises the step S10 of obtaining at least one visual representation of the lighting site to be retrofitted. The at least one visual representation may be any one, or a combination, of: a photograph of the lighting site, a video of the lighting site, a map of the lighting site, a three-dimensional view of the lighting site, a street-level visualization of the lighting site. In various embodiments, the map of the lighting site may be a technical map of the lighting site, an architectural blueprint of the lighting site, a cadastral map, a topographic map, or an architectural project view of the lighting site. More detailed embodiments of the at least one visual representation will be described with reference to FIGS. 4A-4C.

A plurality of visual representations of the lighting site may be obtained. In an embodiment, the plurality of visual representations may be of the same kind and represent different viewpoints of the lighting site. In another embodiment, the plurality of visual representations may comprise visual representations of different kinds.

In a computer controlled system implementing the method, the at least one visual representation may be received on a data entry means and stored in a memory for further processing. The data entry means may comprise at least one interface for reading a storage medium onto which the at least one visual representation has been stored. The storage medium may be a local storage medium of the computer controlled system, e.g. a hard drive, a buffer memory, or may be a remote storage medium. The at least one visual representation may be obtained by a processor of the system from the memory. In an embodiment, the at least one visual representation may be obtained or retrieved from the storage medium based on an address inputted by the user, said address being associated to a location of the lighting site and linked to at least one corresponding visual representation of the lighting site.

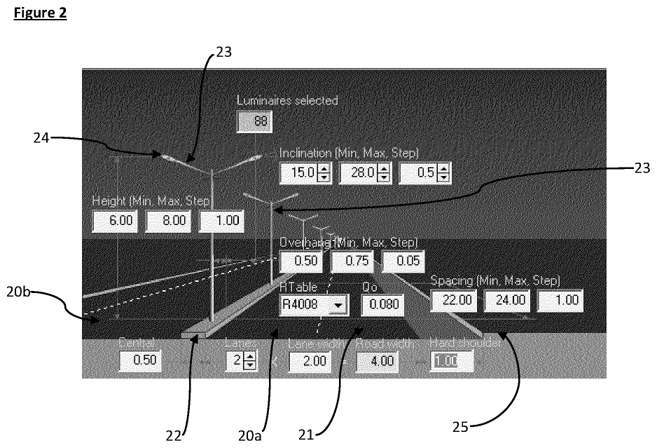

As can be seen in the embodiment of FIG. 1, the method comprises the step S11 of extracting, from the at least one visual representation, at least one luminaire installation characteristic. Preferably, at least two luminaire installation characteristics are extracted, more preferably at least three. Extraction methods based on the processing of the at least one visual representation are not described here but are presumably known to the skilled person. The at least one luminaire installation characteristic may correspond to optical characteristics of the environment of the lighting site to be illuminated, and/or to dimensions relevant for the installation of a luminaire More detailed embodiments of the at least one luminaire installation characteristic will be described with reference to FIG. 2. In an embodiment, the extraction of the at least one installation characteristic may be followed by a manual correction or confirmation of the at least one installation characteristic extracted.

In an embodiment, the extraction of the at least one luminaire installation characteristic may be based on a plurality of visual representations. The plurality of visual representations may be used in order to improve the precision of the extracted at least one luminaire installation characteristic. In another embodiment, the plurality of visual representations may provide complementary information which, when processed, allows the extraction of the at least one luminaire installation characteristic. Different extraction methods may be used on the various visual representations of the lighting site to extract information, and optionally may be further processed. By combining different visual information, one may obtain luminaire installations characteristics not otherwise extractable. Additionally or alternatively, the extraction may take into account data stored in a database relevant to the at least one luminaire installation characteristic of the lighting site.

As can be seen in the embodiment of FIG. 1, the method comprises a step S12 of obtaining, based on the at least one luminaire installation characteristic and a database with a plurality of luminaire designs, a list comprising at least one luminaire design of said plurality of luminaire designs, said at least one luminaire design being suitable for being installed at the lighting site. By suitability, it is meant the ability for the luminaire design to satisfy some lighting standards, e.g. a public road lighting standard such as EN 13201, IES RP-8, CIE 115, respective to the environment of the lighting site, thereby allowing for an illumination giving a visibility above a predetermined level for users of the lighting site, as well as giving a predetermined illumination safety, e.g. illumination intensity below a blinding intensity, light emitted within a certain arc to avoid glaring angles.

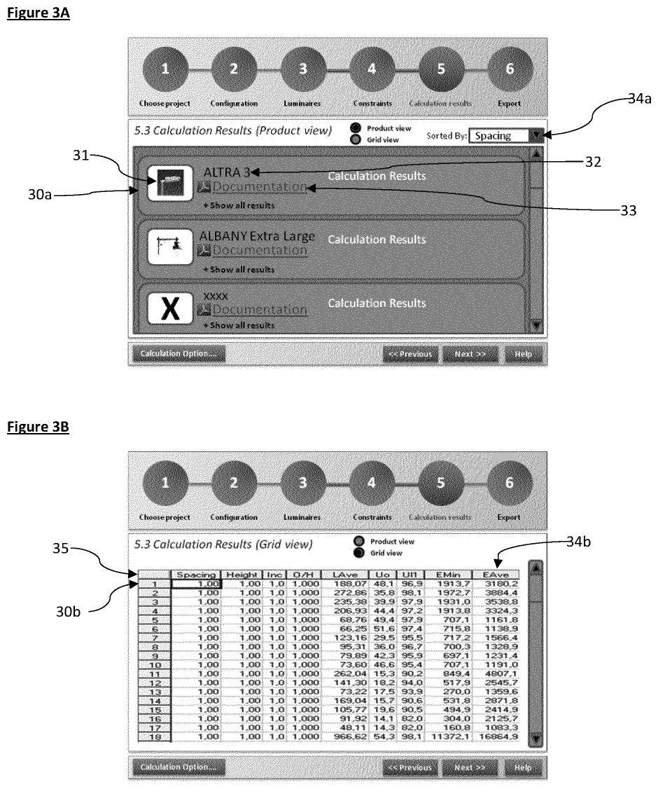

Similarly as the at least one visual representation, in the computer controlled system, the database of the plurality of luminaire designs may be received by the data entry means and stored in the memory of the system. In an embodiment, the database of the plurality of luminaire designs may be available on a server of a luminaire producer. The list may be obtained by the processor of the system and displayed on a display of the system. Each luminaire design on the list may be associated with a summary of the luminaire design including various information, e.g. spacing, height, average luminance of an emitted light, transversal uniformity of the emitted light, longitudinal uniformity of the emitted light, average enlightenment of the emitted light, glare threshold index of the emitted light, luminaire name, lamp/led type and wattage, brand of luminaire parts, driver type, lighting light distribution, luminaire working temperature, lighting life time, luminaire class, luminaire total cost of ownership, luminaire installation method, etc. More detailed embodiments of views of the list will be described with reference to FIGS. 3A-3B.

To obtain the list of the at least one luminaire design, the at least one installation characteristic may be compared to parameters associated to each of the plurality of luminaire designs in the database of luminaire designs to check for a positive correspondence. The positive correspondence may be an indicator of the suitability of the corresponding luminaire design. The parameters associated to each of the plurality of luminaire designs may be any one of: light distribution, lamp/led type and wattage, protectors type, optical components, flux, photometric accessories, light color temperature, luminaire family, light supply current, etc. By an elimination process, the list of at least one suitable luminaire design can be obtained. In an embodiment, no suitable luminaire design can be obtained and the computer controlled system may display a manual input interface to input at least one installation characteristic manually instead of via the at least one visual representation; or the computer controlled system may suggest at least one installation characteristic to be reset to avoid for the list to be void, or may suggest at least one installation characteristic to be modified.

As can be seen in the embodiment of FIG. 1, the method comprises the optional step S13 of sorting the list of the at least one luminaire design based on a preferential parameter. The preferential parameter may be any one of: a light distribution, optical components, photometric accessories, a cost, a technical option, a management option, an aesthetical consideration, a brand of a luminaire part of the at least one luminaire design, a communication protocol, a number of luminaire parts included in the at least one luminaire design, a certification, a luminaire picture, a luminaire name, protectors type (e.g. glass), lamp/led type and wattage, lamp maintenance factor, flux, lamp deprecation factor, maintenance factor, a height of a luminaire head of the at least one luminaire, a bracket length of the luminaire head of the at least one luminaire, an inclination of the luminaire head of the at least one luminaire, a control system of the luminaire, a maximum number of mounting tools to use, etc. For example, the certification may be related to an ecological label of a manufacturing company and/or of luminaire parts of the luminaire design, an IP-rating of the luminaire design, a resistance rating to shocks and/or vibrations, etc. The list will be sorted in rank of correspondence with the selected preferential parameter.

In the computer controlled system, the preferential parameter may be selected through an input interface via an inputting means of the system. The inputting means may be any one of: a touch-sensitive interface, a keyboard, a button, a mouse, etc. In an embodiment, the view of the list displayed on the display of the system may comprise an interface to select the preferential parameter among a preset list of preferential parameters.

As can be seen in the embodiment of FIG. 1, the method comprises the optional step S14 of outputting an altered visual representation of the lighting site with at least one installed luminaire, based on the list of the at least one luminaire design and on the at least one visual representation of the lighting site. Based on the at least one visual representation of the lighting site, a composite altered visual representation of the lighting site may be processed to integrate the picked luminaire design as an installed luminaire on the lighting site. The outputted altered visual representation may be of a similar or different kind as the at least one visual representation. Preferably, the outputted altered visual representation is outputted via an AR (altered reality) device.

In an embodiment of the computer controlled system, a selection interface may be displayed on the display of the system, and a user of the system may input via an inputting means a selected luminaire design part of the list of the at least one luminaire design. After the selection, the system may output an altered visual representation. The list of the at least one luminaire design and the altered visual representation may be outputted via similar or different outputting means, e.g. two different displays included in the system.

As can be seen in the embodiment of FIG. 1, the method comprises the optional step S15 of obtaining another funneling information. The step S15 may be executed before step S12, and/or after step S12, and/or step S13, and/or step S14. The another funneling information may allow to further reduce the number of luminaire designs in the list of the at least one luminaire design. Indeed the another funneling information may be provided when iterating or reiterating step S12 of the method to be taken into account.

In an embodiment, the step S15 may comprise obtaining, from a regulation database, a lighting regulation associated to the lighting site. The lighting regulation may correspond to a legal obligation or recommendation based on the class of the identified pathway, the amount of traffic, the type of users of the pathway, etc. In an embodiment, the obtaining of the lighting regulation may be based on the geo-coordinates of the lighting site. Additionally or alternatively, the obtaining of the lighting regulation may be at least partially based on the extracted installation characteristic, e.g. the number of lanes of the pathway. In an embodiment, the obtaining of the lighting regulation may be followed by a manual correction or confirmation of the lighting regulation associated to the lighting site. Also, the obtaining of the lighting regulation may be achieved by a manual entry.

The regulation database may be a nation-wide database, a region-wide database, a city-wide database, or a local-wide database. In an embodiment, the regulation database may be stored in the memory of the system and the obtaining of the lighting regulation may be achieved by reading the regulation database in the memory. In another embodiment, the system may further comprise a communication means configured for communication with the regulation database located remotely.

In an embodiment, the step S15 may comprise obtaining, from a stock database, a list of available luminaire parts. In an embodiment, the stock database may be stored in the memory of the system and the obtaining of the list of available luminaire parts may be achieved by reading the stock database in the memory. In another embodiment, the system may further comprise a communication means configured for communication with the stock database located remotely. In this way, the obtained list of the at least one luminaire design in step S12 reflects an actual product availability.

Indeed the luminaire design may comprise a certain number of luminaire parts to be gathered with various parts being essential or interchangeable. The availability of luminaire parts may change the overall characteristics of a luminaire design. The stock database may be luminaire parts available in a stock of a local provider, in a stock of a luminaire producer, in a catalogue of products, or in a personal stock. The availability may be further distinguished between available in stocks, discontinued, in production, and/or with a time indication of the availability on the lighting site for installation. The list of available luminaire parts may also comprise a quantity of available luminaire parts, an end-of-life date of available luminaire parts, a manufacturing country of the luminaire parts, an ecological label of the luminaire parts. In an embodiment, the obtaining of the list of the at least one luminaire design may be based on luminaire designs favoring available luminaire parts whose quantity in stocks is high, which are subject to a special price offer, and/or which are close to the end-of-life date.

In an embodiment, the step S15 may comprise providing an input corresponding to another luminaire installation characteristic via an input interface. Other luminaire installation characteristics may thus be conveniently inputted from various sources. For example the input provided may be a manual input by a user using an inputting means, e.g. a keyboard. Additionally or alternatively, the another luminaire installation characteristic may originate from a database of known luminaire installation characteristics and/or based from on-site measured data.

In an embodiment, the step S15 may comprise obtaining another at least one luminaire installation characteristic of another lighting site. The at least one luminaire installation characteristic and the another at least luminaire installation characteristic may be of similar or different kinds. In one embodiment, the another lighting site does not need to be retrofitted and the another at least one luminaire installation characteristic allows to improve the likeness in the list of the at least one luminaire design obtained in step S12 between the lighting site and the another lighting site. In another embodiment, the another lighting site is to be retrofitted and the obtaining of the list of the at least one luminaire design of step S12 allows optimizing the suitability to multiple lighting sites. It is to be noted that the another at least one luminaire installation characteristic may be provided manually, and/or extracted from an obtained visual representation, and/or originate from a database.

In an embodiment, the step S15 may obtain the another funneling information from the sorted list after step S13, and the reiteration of step S12 may allow to remove from the list at least one of the luminaire design at the bottom of the sorted list.

In an embodiment, the step S15 may obtain the another funneling information via an input from the user of the computer controlled system after a negative appreciation of the outputted altered visual representation of step S14.

In an embodiment, the step S12 may be followed by another step comprising the provision of a purchase selection interface. The purchase selection interface may allow the user, after selection of the at least one desired luminaire design from the list of the at least one luminaire design, to conclude by ordering the at least one desired luminaire design for retrofitting the lighting site.

FIG. 2 depicts an outline of a lighting site according to an exemplary embodiment of the present invention. From the lighting site, various luminaire installation characteristics may be extracted which are relevant for processing the obtention of a suitable luminaire design.

The typical lighting site depicted in the embodiment of FIG. 2 comprises at least one pathway, more particularly two roads 20a, 20b in the embodiment of FIG. 2. Each of the two roads 20a, 20b may comprise a given number of lanes 21, two lanes 21 for each of the roads 20a, 20b. Depending on the configuration of the pathway, different vehicles may use said pathway. The roads 20a, 20b of FIG. 2 are adapted only for motor-driven vehicles. Depending on the configuration of the pathway, a direction of traffic may be identified, with the traffic direction being similar or different for each lane 21. The road 20a on the right side of FIG. 2 may have a traffic direction away from the viewer with its two lanes 21 having similar traffic directions, and the road 20b on the left side of FIG. 2 may have a traffic direction towards the viewer with its two lanes 21 having similar traffic directions. The two roads 20a, 20b may be separated by a central element 22 with a given width. The roads 20a, 20b and/or lanes 21 may each have a specific width in a direction perpendicular to the traffic direction.

The lighting site may have at least one luminaire 23 installed to be retrofitted, a plurality of luminaires 23 in the embodiment of FIG. 2. Each of the plurality of luminaires 23 may comprise one of more luminaire head 24, for example two luminaire heads 24 per luminaire 23. Two luminaires 23 may be located at a specific spacing from each other. In the case of a motorway, for example, this spacing may be a regular interval between each of the luminaires 23.

The luminaire 23 may comprise a base support, e.g. a pole, onto which the luminaire head 24 is mounted, optionally in association with a luminaire head bracket. Various dimensions may be identified with respect to the luminaire 23: a height of the base support, an overhang of the luminaire head 24 with respect to the base support, an inclination of the luminaire head 24 with respect to a horizontal direction, a lateral dimension of a hard shoulder of the pathway, an arrangement pattern of a group of luminaires including the at least one luminaire, a location of the at least one luminaire base support respective to the one or more circulation directions. Also an optical characteristic of the surface to be illuminated may be obtained, e.g. the reflective optical characteristics of the surface.

FIGS. 3A-3B depict two different views of a list of luminaire designs obtained according to exemplary embodiments of the present invention.

FIG. 3A depicts a product view of the list of the at least one luminaire design obtained according to the method of the present invention. FIG. 3B depicts a grid view of the list of the at least one luminaire design obtained by the method of the present invention. In the embodiments of FIGS. 3A-3B, the list may be outputted via a display of a computer controlled system. Via an inputting means of the system, a user of the system may alternate between the view of FIG. 3A and the view of FIG. 3B.

FIG. 3A presents the list of the at least one luminaire design in a marketing view which is more user-friendly. Each of the at least one luminaire design part of the list is displayed in a separate presentation box 30a of the list. Various information are associated to each luminaire design and presented in the presentation box 30a. On the left side of the box, a picture 31 of the luminaire design depicts an real view of the product corresponding to the luminaire design. The picture 31 of the luminaire design is accompanied on its right side by a luminaire name 32, and a link 33 to a PDF documentation of the luminaire design. The list of FIG. 3A can be sorted according to a selected preferential parameter 34a. The preferential parameter 34a may be selected via a selection interface, e.g. a drop-down menu, displayed on the display of the system. The sorting in FIG. 3a may be achieved based on any one of the following parameters: a spacing, a height, an average luminance of an emitted light, a transversal uniformity of the emitted light, a longitudinal uniformity of the emitted light, an average enlightenment of the emitted light, a glare threshold index of the emitted light, brand of luminaire parts, driver type, a lighting light distribution, a luminaire working temperature, a lighting life time, a luminaire class, a luminaire total cost of ownership, a luminaire installation method, etc.

FIG. 3B presents the list of the at least one luminaire design in a more comprehensive view showing different parameters of each luminaire design. The luminaire design parameters 35 are corresponding to the columns of the grid view of FIG. 3B. Each row of the grid view, apart from the first one, corresponds to a different luminaire design 30b. The luminaire design parameters 35 may be: a spacing, a height, an overhang, an average luminance of an emitted light, a transversal uniformity of the emitted light, a longitudinal uniformity of the emitted light, an average enlightenment of the emitted light, a glare threshold index of the emitted light, luminaire name, a lamp/led type and wattage, brand of luminaire parts, driver type, a lighting light distribution, a luminaire working temperature, a lighting life time, a luminaire class, a luminaire total cost of ownership, a luminaire installation method, etc. The list presented in the grid view of FIG. 3B may be sorted according to the luminaire design parameters 35 of each column. In an embodiment, a tooltip may be displayed with various information in a similar manner as the presentation box 30a of FIG. 3A. The tooltip may be displayed when a mouse hovers the row of the luminaire design 30b in the grid view.

In other embodiments, the sorting in FIGS. 3A-3B may alternatively be based on any one of: a cost, a technical option, a management option, an aesthetical consideration, maintenance factors, a brand of a luminaire part of the at least one luminaire design, a protocol such as communication protocol, a number of luminaire parts included in the at least one luminaire design, a certification, etc. For example, the certification may be related to an ecological label of a manufacturing company and/or of luminaire parts of the luminaire design, an IP-rating of the luminaire design, a resistance rating to shocks and/or vibrations, etc.

FIGS. 4A-4C depict visual representations of a lighting site according to exemplary embodiments of the present invention.

FIG. 4A is a photo of a lighting site to be retrofitted. FIG. 4B is a hybrid satellite view of the lighting site of FIG. 4A. FIG. 4C is an architectural map of another lighting site to be retrofitted.

In the embodiment of FIG. 4A, the lighting site represented is at a cross-road of two city streets. A luminaire 40 to be retrofitted is installed at a corner of the cross-road. The luminaire 40 is pole-mounted. The luminaire 40 is neighboring a pedestrian crossing 41, and rails 42 of a passing tramway. Two sets of rails 42 are present in FIG. 4A and it can be deducted that the traffic goes in both directions. Additionally, vehicles such as cars can also circulate on the two sets of rails 42. With reference to FIG. 2, various information corresponding to luminaire installation characteristics may be extracted from FIG. 4A. The extracted luminaire installation characteristics may be at least: a luminaire height 43, a luminaire overhang 44, a width of the street 45, a number of lanes, a traffic direction, a type of pathway user, a spacing 46 between the pole-mounted luminaire 40 and the neighboring wall-mounted luminaire, a proximity to a neighboring building, characteristics of the neighboring buildings, etc.

FIG. 4B represents another visual representation of the lighting site of FIG. 4A. A location 40′ of the luminaire to be retrofitted has been added a posteriori after obtaining the satellite view. The location 40′ is identified by a white star in the another visual representation. A scale 47 can be present on the another visual representation in order to ease dimensions evaluation during the extraction of the at least one luminaire installation characteristic. The visual representations of FIGS. 4A and 4B may be used jointly in order to extract the at least one luminaire installation characteristic. For example, one of the two city streets of the cross-road in FIG. 4A is less visible on the photo, and FIG. 4B may be used to obtain more accurate information of the other city street of the cross-road. The satellite view of FIG. 4B may be associated with geo-coordinates of the lighting site. In an embodiment, the geo-coordinates of the lighting site may be used in order to obtain a lighting regulation of the lighting site.

In the embodiment of FIG. 4C, the lighting site may be an entire city neighborhood and the lighting site can be better visualized using an architectural map with a top view of the city neighborhood. The locations of the luminaires to be retrofitted on the lighting site may be identified with black dots. The list of the at least one luminaire design may comprise a plurality of sub-lists, each of the sub-lists corresponding to a different type of building or place in the city neighborhood in order to adapt the luminaire design to the function of each area.

The visual representations of the embodiments of FIG. 4A-4C may be utilized to obtain the list of the at least one luminaire design. According to an embodiment, the obtaining of the list of the at least one luminaire design may be further based on another at least one luminaire installation characteristic of another lighting site. In this manner, a certain uniformity between lighting sites may be attained. For example, the lighting site to be retrofitted may correspond to FIG. 4A or FIG. 4B and the another lighting site may correspond to FIG. 4C. The at least one luminaire installation characteristic and the another at least luminaire installation characteristic may be of similar or different kinds. In one embodiment, the another lighting site does not need to be retrofitted and the another at least one luminaire installation characteristic allows to improve the likeness in the list of the at least one luminaire design between the lighting site and the another lighting site. In another embodiment, the another lighting site is to be retrofitted and the obtaining of the list of the at least one luminaire design allows optimizing the suitability to multiple lighting sites. It is to be noted that the another at least one luminaire installation characteristic may be provided manually, and/or extracted from an obtained visual representation, and/or originate from a database.

Whilst the principles of the invention have been set out above in connection with specific embodiments, it is to be understood that this description is merely made by way of example and not as a limitation of the scope of protection which is determined by the appended claims.

1. A method for retrofitting a lighting site, said lighting site including at least one pathway, said method comprising:
obtaining at least one visual representation of the lighting site to be retrofitted, said lighting site corresponding to a location for installing at least one luminaire;
extracting, from the at least one visual representation, at least one luminaire installation characteristic; and
obtaining, based on the at least one luminaire installation characteristic and a database with a plurality of luminaire designs, a list comprising at least one luminaire design of said plurality of luminaire designs, said at least one luminaire design being suitable for being installed at the lighting site.

2. The method according to claim 1, wherein the at least one luminaire installation characteristic is at least one of, preferably at least two of, more preferably at least three of: a pathway width, an interval distance between two neighboring luminaire base supports, a pathway surface material, a pathway surface optical properties, a height of a luminaire head of the at least one luminaire, a number of lanes of the pathway, one or more circulation directions of the pathway, a lateral distance between the pathway and the at least one luminaire base support, a lateral dimension of a hard shoulder of the pathway, an arrangement pattern of a group of luminaires including the at least one luminaire, a bracket length of the luminaire head of the at least one luminaire, an inclination of the luminaire head of the at least one luminaire, a location of the at least one luminaire base support respective to the one or more circulation directions, a proximity with a neighboring building, characteristics of the neighboring building, a number of luminaire heads per base support, a presence of a conflict area in the lighting site, or a type of the pathway.

3. The method according to claim 1, wherein the method further comprises
providing an input corresponding to another luminaire installation characteristic and
wherein the obtaining of the list of the at least one luminaire design is further based on the another luminaire installation characteristic.

4. The method according to claim 1, wherein the method further comprises:
providing an input corresponding to a preferential parameter relative to the plurality of luminaire designs; and
sorting the list of the at least one luminaire design based on the preferential parameter.

5. The method according to claim 1, wherein the method further comprises
obtaining, from a regulation database, a lighting regulation associated to the lighting site and
wherein the obtaining of the list of the at least one luminaire design is further based on the obtained lighting regulation.

6. The method according to claim 1, wherein the method further comprises
obtaining, from a stock database, a list of available luminaire parts and
wherein the obtaining of the list of the at least one luminaire design is further based on the obtained list of available luminaire parts.

7. The method according to claim 1, wherein the method further comprises
outputting an altered visual representation of the lighting site with at least one installed luminaire, based on the list of the at least one luminaire design and on the at least one visual representation of the lighting site.

8. (canceled)

9. The method according to claim 1, wherein the at least one visual representation comprises a first and a second visual representation of the lighting site, said first visual representation being different from said second visual representation and
wherein the extracting of the at least one luminaire installation characteristic is based on the first and the second visual representations of the lighting site.

10. The method according to claim 1,
wherein the obtaining of the list of the at least one luminaire design is further based on another at least one luminaire installation characteristic of another lighting site.

11. The method according to claim 1, wherein the at least one visual representation comprises an indication corresponding to a location of the at least one luminaire base support within the lighting site.

12. The method according to claim 1, wherein the lighting site corresponds to the location for installing, for the at least one luminaire, at least one luminaire head, optionally combined with an associated luminaire head bracket, to at least one existing base support of the lighting site.

13. A computer program comprising instructions which, when the program is executed by a computer, cause the computer to carry out the method according to claim 1.

14. A computer controlled system for retrofitting a lighting site, said lighting site including at least one pathway, said system including:
a data entry means adapted to receive:
at least one visual representation of the lighting site to be retrofitted, said lighting site corresponding to a location for installing at least one luminaire; and
a database comprising a plurality of luminaire designs;
a memory coupled to said data entry means for storing said at least one visual representation, and said database comprising the plurality of luminaire designs;
a processor coupled to said memory; and
a display coupled to said processor,
wherein the processor is further configured for:
obtaining, from the memory, the at least one visual representation of the lighting site;
extracting from the at least one visual representation at least one luminaire installation characteristic;
obtaining, based on the at least one luminaire installation characteristic, a list of at least one luminaire design of the plurality of luminaire designs, said at least one luminaire design being suitable for being installed at the luminaire site; and
outputting the list of the at least one luminaire design via the display.

15. The computer controlled system according to claim 14, wherein the processor is further configured for:
providing an input interface for inputting another installation characteristic; and
obtaining the list of the at least one luminaire design further based on the another installation characteristic.

16. The computer controlled system according to claim 14, wherein the processor is further configured for:
providing an input interface for inputting a preferential parameter; and
sorting the list of the at least one luminaire design based on the preferential parameter.

17. (canceled)

18. The computer controlled system according to claim 14, further comprising a stock database, wherein the processor is further configured for:
obtaining, from the stock database, a list of available luminaire parts; and
obtaining the list of the at least one luminaire design further based on the obtained list of available luminaire parts.

19. The computer controlled system according to claim 14, further comprising an inputting means configured for inputting, through the inputting means via a selection interface, a selected luminaire design from the list of the at least one luminaire design, wherein the processor is configured for:
altering the at least one visual representation of the lighting site with at least one installed luminaire, based on the list of the at least one luminaire design and on the at least one visual representation of the lighting site; and
outputting the at least one altered visual representation via the display, and/or outputting the at least one altered visual representation via another display included in the computer controlled system.

20. The computer controlled system according to claim 14, wherein the data entry means is further adapted to receive
a second visual representation of the lighting site different from a first visual representation of the at least one visual representation and
wherein the processor is further configured for
extracting the at least one luminaire installation characteristic based on the first and on the second visual representations of the lighting site.

21. The computer controlled system according to claim 14,
wherein the processor is further configured for
obtaining the list of the at least one luminaire design further based on another at least one luminaire installation characteristic of another lighting site.

22. A method for retrofitting a lighting site, said lighting site including at least one pathway, said method comprising:
obtaining, based on at least one luminaire installation characteristic and a database with a plurality of luminaire designs, a list comprising at least one luminaire design of said plurality of luminaire designs, said at least one luminaire design being suitable for being installed at the lighting site,
wherein the obtaining of the list of the at least one luminaire design is further based on another at least one luminaire installation characteristic of another lighting site.
